(19) United States
(12) Patent Application Publication
(10) Pub. No.: US 2012/0193813 A1
(43) Pub. Date: Aug. 2, 2012

(54) WIRING STRUCTURE OF SEMICONDUCTOR DEVICE AND METHOD OF MANUFACTURING THE WIRING STRUCTURE

(75) Inventor: Hiroyuki NUMAGUCHI, Miyazaki (JP)

(73) Assignee: LAPIS Semiconductor Co., Ltd., Tokyo (JP)

(21) Appl. No.: 13/363,407

(22) Filed: Feb. 1, 2012

(30) Foreign Application Priority Data
Feb. 2, 2011 (JP) 2011-020489

(51) Int. Cl. H01L 23/538; H01L 21/768

(52) U.S. Cl. 257/774; 438/666; 257/E23.174; 257/E21.585

(57) ABSTRACT

A wiring structure of a semiconductor device, includes: an insulating layer formed on a base member; a first metal layer covered with the insulating layer; a second metal layer having a plurality of electrode parts which are arranged on the insulating layer to be spaced from each other and which have a thickness larger than the first metal layer, the insulating layer having a plurality of via holes which connect the first metal layer and the plurality of electrode parts; and a plurality of through wiring lines which are located within the plurality of via holes and which electrically connect the plurality of electrode parts to the first metal layer.

### BACKGROUND OF THE INVENTION

1. Field of the Invention

The present invention relates to a wiring structure of a semiconductor device and a method of manufacturing the wiring structure of a semiconductor device.

2. Description of the Related Art

In the prior art, such a wiring structure of a semiconductor device as illustrated in FIG. 1 showing a plan view and FIG. 2 showing a cross-sectional view taken along a line II-II in FIG. 1, is widely known. The wiring structure includes an insulating layer 2 formed on a silicon substrate 1, a first metal layer 3 covered with the insulating layer 2, a second metal layer 4 as a pad electrode located on the insulating layer 2, and a wiring line 5 connected to the second metal layer 4.

However, when a temperature of metal of the second metal layer 4 in its thermally-expanded state is decreased during sputtering of the second metal layer, a shrinkage force of the metal coated on the insulating layer 2 causes such stresses as directed internally inwardly in the second metal layer to take place. Thereafter, when an unnecessary part of the metal is etched to form such a second metal layer 4 as shown in FIG. 1, stresses present in the interior of the second metal layer becomes force expressed by an arrow shown by F1a in FIGS. 1 and 2, and such a force as to withstand a stress within the second metal layer 4 takes place in the interior of the insulating layer 2 closely contacted with the second metal layer 4. This may cause, in some cases, a crack (shown by reference numeral 6 in FIG. 2) to take place in the insulating layer 2 (in particular, in the vicinity of four corners of the second metal layer 4). Generation of the crack 6 may, in some cases, cause a chemical solution used for cleaning after the etching to flow into the insulating layer 2 and to reach as far as the first metal layer 3, thus unfavorably resulting in corrosion of the first metal layer 3 and so on.

In order to reduce a stress (force generated in a direction opposed to the arrow of FIG. 1) generated when a wiring conductor is bonded to the second metal layer 4 as a pad electrode, such a measure to provide a through hole in the wiring line of the pad electrode is disclosed, for example, in Japanese Patent Kokai Publication No. 63-141330 (e.g., FIGS. 1A and 1B in this document), which will be referred to as Patent Document 1.

However, even when the measure disclosed in Patent Document 1 is taken, reduction of the stress generated when the wiring conductor is bonded is insufficient. Such force as to withstand the stress of the second metal layer 4 takes place, which causes generation of a crack in the insulating layer 2 (in particular, in the vicinity of the corners of the second metal layer 4), with a result of an undesirable defect caused by the crack.

As has been described above, the prior art wiring structure of the semiconductor device has such a problem that a crack takes place in the insulating layer closely contacted with the metal layer as a pad electrode after the sputtering or upon the bonding, leading to the fact that a defect tends to be caused by the crack.

### SUMMARY OF THE INVENTION

It is therefore an object of the present invention to provide a wiring structure of a semiconductor device which makes it possible to avoid generation of a crack in an insulating layer closely contacted with a second metal layer, and a method of manufacturing the wiring structure of a semiconductor device.

According to an aspect of the present invention, a wiring structure of a semiconductor device, includes: an insulating layer formed on a base member; a first metal layer covered with the insulating layer; and a second metal layer having a plurality of electrode parts which are arranged on the insulating layer to be spaced from each other and which have a thickness larger than the first metal layer; wherein the insulating layer has a plurality of via holes which connect the first metal layer and the plurality of electrode parts. The wiring structure further includes a plurality of through wiring lines which are located within the plurality of via holes and which electrically connect the plurality of electrode parts to the first metal layer.

According to another aspect of the present invention, a method of manufacturing a wiring structure of a semiconductor device, includes: forming a first insulating layer on a base member; forming a first metal layer on the first insulating layer; forming a second insulating layer covering the first metal layer; forming a plurality of via holes in the second insulating layer; forming a plurality of through wiring lines which are provided within the plurality of via holes to be electrically connected to the first metal layer; and forming a plurality of electrode parts which are arranged on the second insulating layer to be spaced from each other and are electrically connected to any of the plurality of through wiring lines, the plurality of electrode parts constituting the second metal layer and having a thickness larger than the first metal layer.

A wiring structure of a semiconductor device and a method of manufacturing the wiring structure in the present invention, make it possible to avoid generation of a crack in an insulating layer closely contacted with a second metal layer, thus improving the quality of the wiring structure.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a plan view schematically showing a prior art wiring structure of a semiconductor device;

FIG. 2 is a cross-sectional view schematically showing the wiring structure of FIG. 1 taken along a line II-II;

FIG. 3 is a plan view schematically showing the wiring structure of the semiconductor device of a first embodiment;

FIG. 4 is a cross-sectional view schematically showing the wiring structure of FIG. 3 taken along a line IV-IV;

FIG. 5 is a cross-sectional view schematically showing the wiring structure of FIG. 3 taken along a line V-V;

FIG. 6 is a cross-sectional view schematically showing the wiring structure of FIG. 3 taken along a line VI-VI;

FIGS. 7A to 7D are diagrams showing processes in a method of manufacturing the wiring structure of the semiconductor device according to the first embodiment;

FIG. 8 is a diagram for explaining the effects of the wiring structure of the semiconductor device according to the first embodiment;

FIG. 9 is a diagram for explaining a wiring structure of a semiconductor device as a comparative example;

FIG. 10 is a plan view schematically showing a wiring structure of a semiconductor device according to a second embodiment;

FIG. 11 is cross-sectional view schematically showing the wiring structure of FIG. 10 taken along a line XI-XI;

FIG. 12 is a cross-sectional view schematically showing the wiring structure of FIG. 10 taken along a line XII-XII; and

FIG. 13 is a cross-sectional view schematically showing the wiring structure of FIG. 10 taken along a line XIII-XIII.

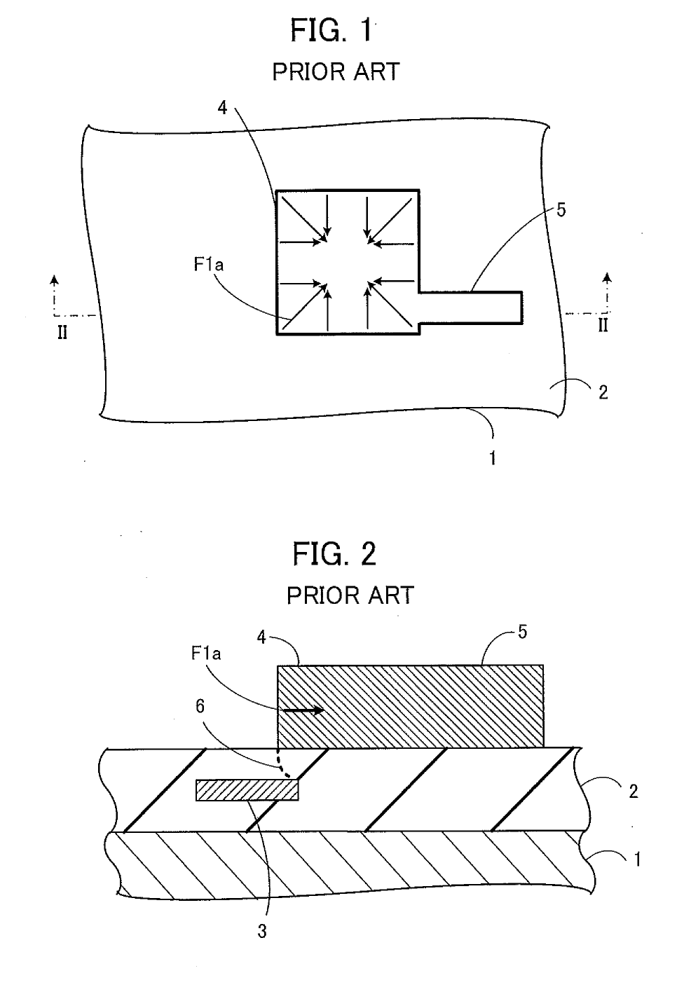

### DETAILED DESCRIPTION OF THE INVENTION

Further scope of applicability of the present invention will become apparent from the detailed description given hereinafter. However, it should be understood that the detailed description and specific examples, while indicating preferred embodiments of the invention, are given by way of illustration only, since various changes and modifications will become apparent to those skilled in the art from the detailed description.

### First Embodiment

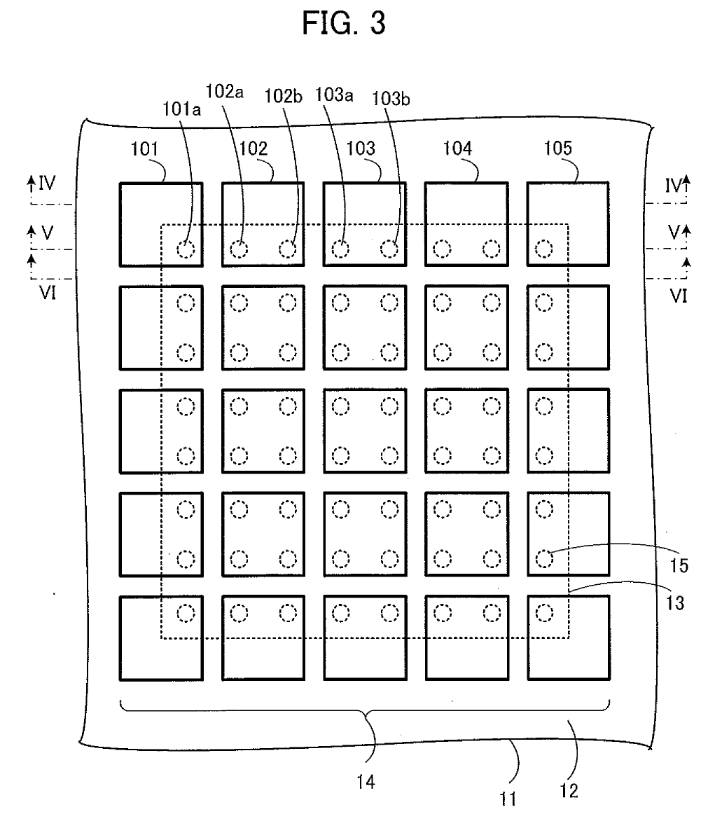

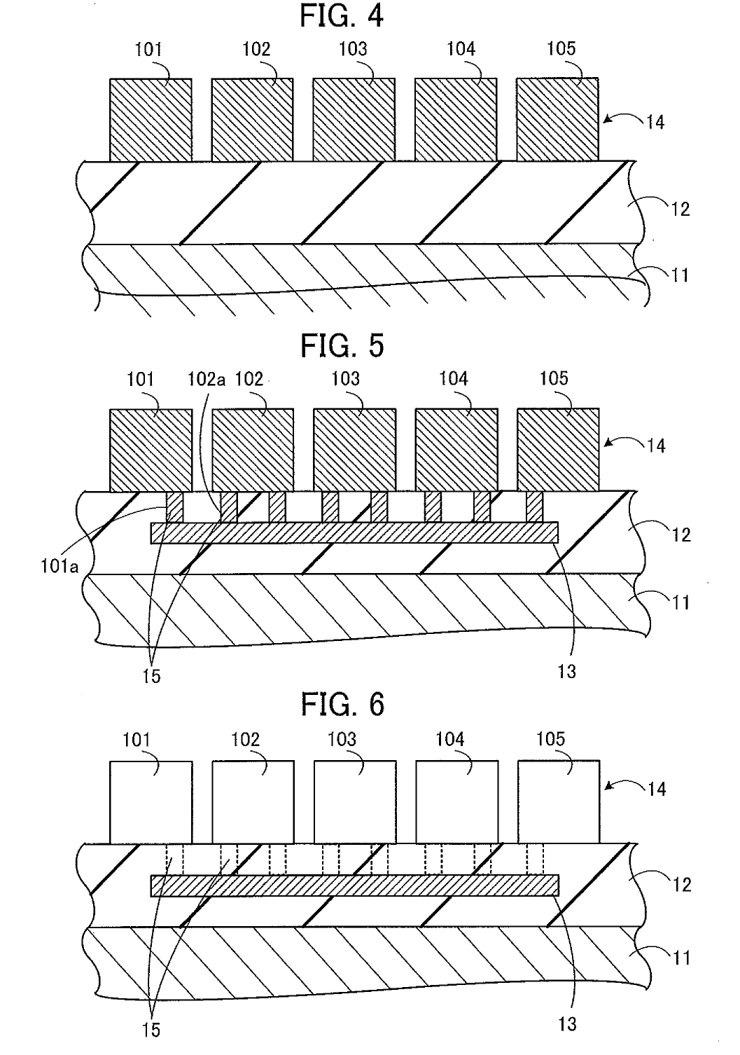

First, an arrangement of a first embodiment will be described. FIG. 3 shows a plan view schematically showing a wiring structure of a semiconductor device according to the first embodiment, FIG. 4 is a cross-sectional view schematically showing the wiring structure of FIG. 3 taken along a line IV-IV, FIG. 5 is a cross-sectional view schematically showing the wiring structure of FIG. 3 taken along a line V-V, and FIG. 6 is a cross-sectional view schematically showing the wiring structure of FIG. 3 taken along a line VI-VI.

As shown in FIGS. 3 to 6, the wiring structure of the semiconductor device according to the first embodiment include an insulating layer (e.g., an SiO₂ layer) 12 formed on a semiconductor substrate (e.g., a silicon substrate) 11 as a base member, a first metal layer 13 as a wiring layer covered with the insulating layer 12, and a second metal layer 14 having a plurality of electrode parts 101, 102, 103, 104, 105, . . . , and so on arranged on the insulating layer 12 to be spaced from each other and having a thickness larger than that of the first metal layer 13. The insulating layer 12 has a plurality of via holes (e.g., 101a, 102a, 102b, 103a, 103b, . . . , and so on) passed through the insulating layer between the first metal layer 13 and the plurality of electrode parts 101, 102, 103, 104, 105, . . . , and so on. A plurality of through wiring lines 15 for electrically connecting the plurality of electrode parts 101, 102, 103, 104, 105, . . . , and so on and the first metal layer 13 are provided within the plurality of via holes.

The plurality of electrode parts 101, 102, 103, 104, 105, . . . , and so on are arranged in plural rows and in plural columns (five rows and five columns in the present embodiment). However, the numbers of rows and columns in the array or matrix are not limited to the illustrated example, and may be other numbers of rows and columns such as four rows and four columns, three rows and three columns, or five rows and six columns.

Each of the plurality of electrode parts 101, 102, 103, 104, 105, . . . , and so on has an approximately quadrangular shape (square or rectangular shape in the illustrated example) in a plan view. However, each of the plurality of electrode parts 101, 102, 103, 104, 105, . . . , and so on are not limited to the quadrangular shape and may have another shape such as a circular shape, an elliptic shape, or a polygonal shape having three corners, or five or more corners.

The plurality of via holes 101a, 102a, 102b, 103a, 103b, . . . , and so on are located in the vicinity of corners of the plurality of electrode parts. However, the plurality of via holes 101a, 102a, 102b, 103a, 103b, . . . , and so on may be located at other positions.

In the first embodiment, the first metal layer 13 is made of a single structural member, and this is located to be opposed to the plurality of electrode parts 101, 102, 103, 104, 105, . . . , and so on, with part of the insulating layer 12 located therebetween.

The first metal layer 13, the through wiring lines 15, and the second metal layer 14 may be made of the same conductive material such as aluminum, copper, an alloy containing any of these materials, or another conductive material.

The base member may be another layer formed on the semiconductor substrate such as another insulating layer and so on (not illustrated in the figure).

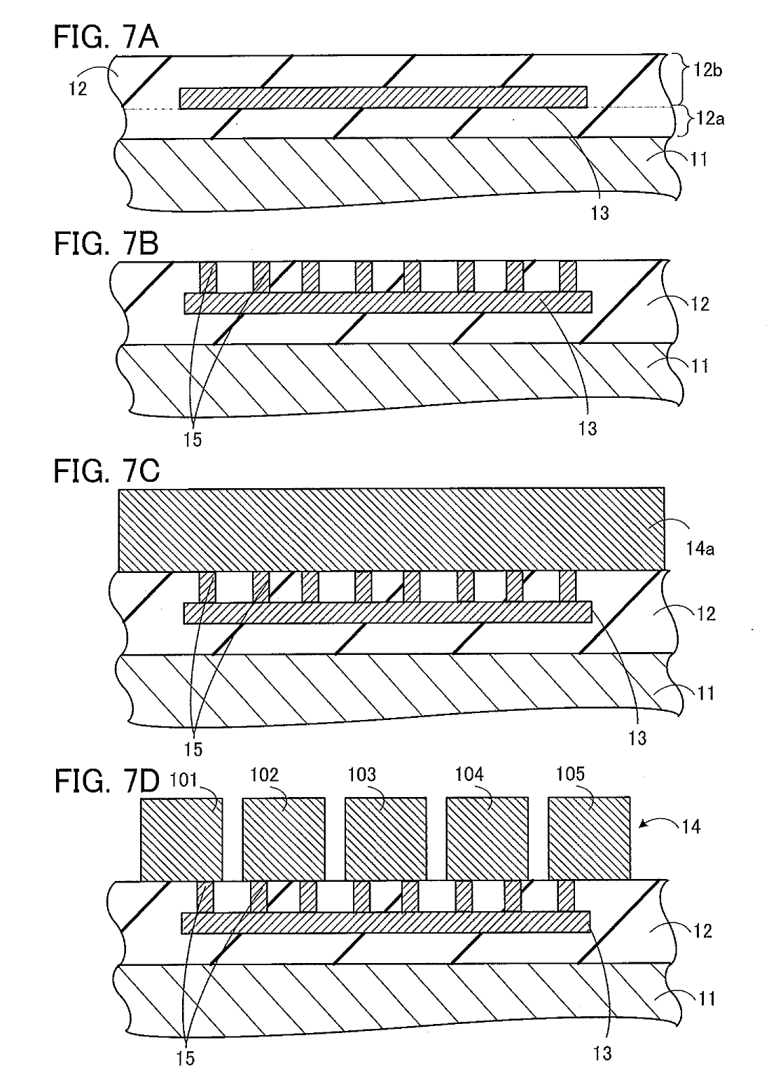

Next, a manufacturing method of the first embodiment will be described. FIGS. 7A to 7D are diagrams showing processes in the method of manufacturing the wiring structure of the semiconductor device according to the first embodiment. In the method of the first embodiment, as shown in FIG. 7A, a first insulating layer 12a is formed on the semiconductor substrate 11 using a known film forming process, a first metal layer 13 is formed on the first insulating layer 12a using a known film forming process such as a sputtering process, a second insulating layer 12b is formed to cover the first metal layer using a known film forming process, and then subjected to known flattening treatment. In this connection, the insulating layer 12 is formed to have the first insulating layer 12a and the second insulating layer 12b.

Next, as shown in FIG. 7B, a plurality of via holes 101a, 102b, . . . , and so on are formed in the second insulating layer 12b using a known process such as a photolithography technique, and a plurality of through wiring lines 15 are formed within the plurality of via holes to be electrically connected to the first metal layer.

As shown in FIG. 7C, a second metal layer 14a is formed using a known film forming process such as sputtering process.

As shown in FIG. 7D, the second metal layer 14a is divided into a plurality of electrode parts 101, 102, 103, 104, 105, . . . , and so on as a pad electrode by using a known process such as a photographic technique. Through the aforementioned processes, the wiring structure of the semiconductor device according to the first embodiment is manufactured.

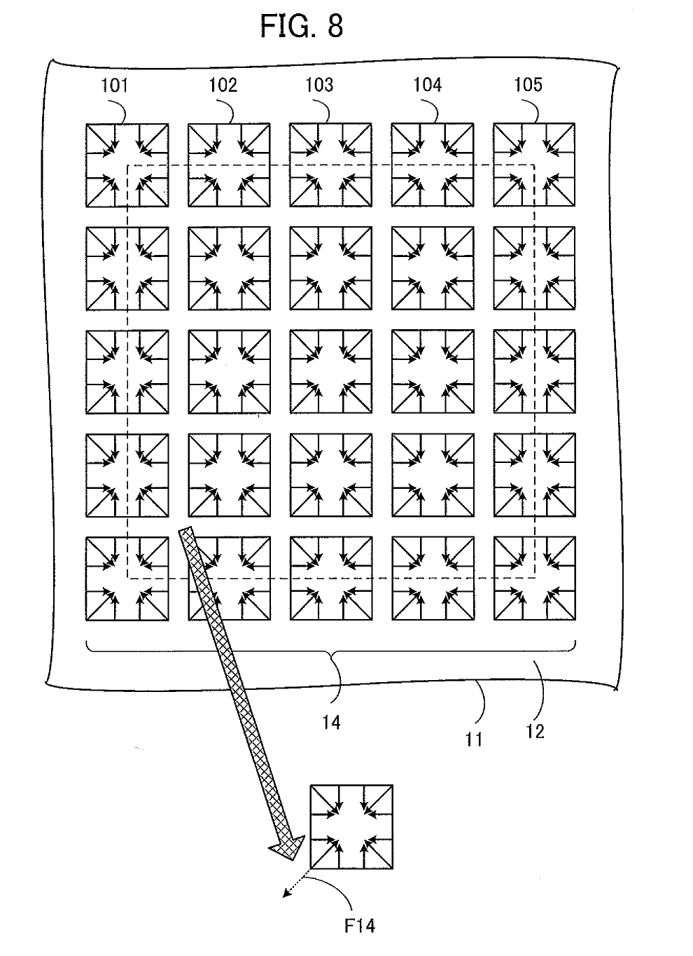

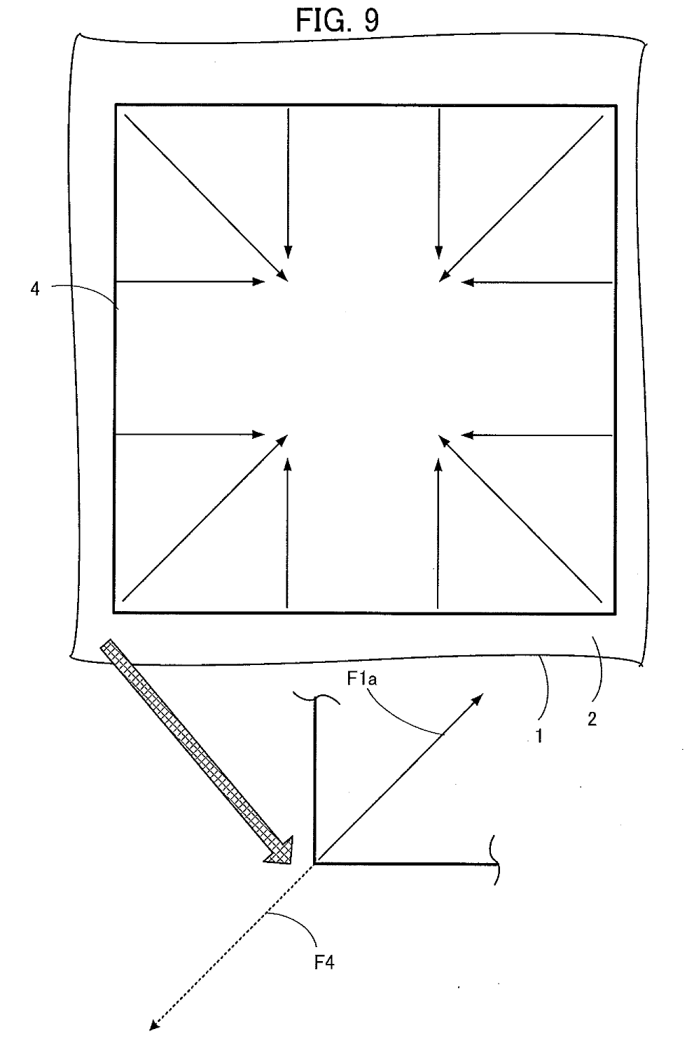

Advantageous effects of the first embodiment will be described. FIG. 8 is a diagram for explaining the effects of the wiring structure of the semiconductor device according to the first embodiment, and FIG. 9 is a diagram for explaining a wiring structure of a semiconductor device as a comparative example. As shown in FIG. 8, with the wiring structure of the semiconductor device according to the first embodiment, the electrode pad is made of a plurality of electrode parts 101, 102, 103, 104, 105, . . . , and so on. Thus, stresses generated within the respective electrode parts are dispersed into the interior of the electrode pad 14 and into a wide range of periphery thereof, for example, as shown by arrows in FIG. 8, so that forces caused by stresses (shown by solid-line arrows) within the respective electrode parts will not be concentrated. For this reason, a force F14 (shown by a dashed-line arrow) when the insulating layer 12 undergoes from the respective electrode parts of the electrode pad 14 is relatively small and this hardly causes a crack to be generated in the insulating layer 12.

As shown in FIG. 9, if the electrode pad 4 is made of a single electrode part, then stresses generated within the electrode pad 4 are concentrated in four corners of the electrode pad 4 and thus forces caused by the stresses (shown by solid-line arrows) are concentrated on a specific location of the insulating layer 2, for example, as shown by arrows. For this reason, a force F4 (shown by a dashed-line arrow) when the insulating layer 2 undergoes from the electrode parts of the second metal layer 4 becomes large and this easily causes generation of a crack in the insulating layer 2.

With the wiring structure of the semiconductor device according to the first embodiment, since the first metal layer 13 is made of a single wiring structural member, stresses generated within the first metal layer 13 are concentrated on a specific location of the insulating layer 12. However, since the first metal layer 13 is formed to be thinner than the pad electrode, a force when the insulating layer 12 undergoes is relatively small and thus the insulating layer 22 is less influenced by such a force.

As has been described above, the wiring structure of the semiconductor device and the method of manufacturing the semiconductor device according to the first embodiment make it possible to reduce generation of a crack in the insulating layer 12 closely contacted with the second metal layer 14, thus improving the quality and reliability of the wiring structure of the semiconductor device.

### Second Embodiment

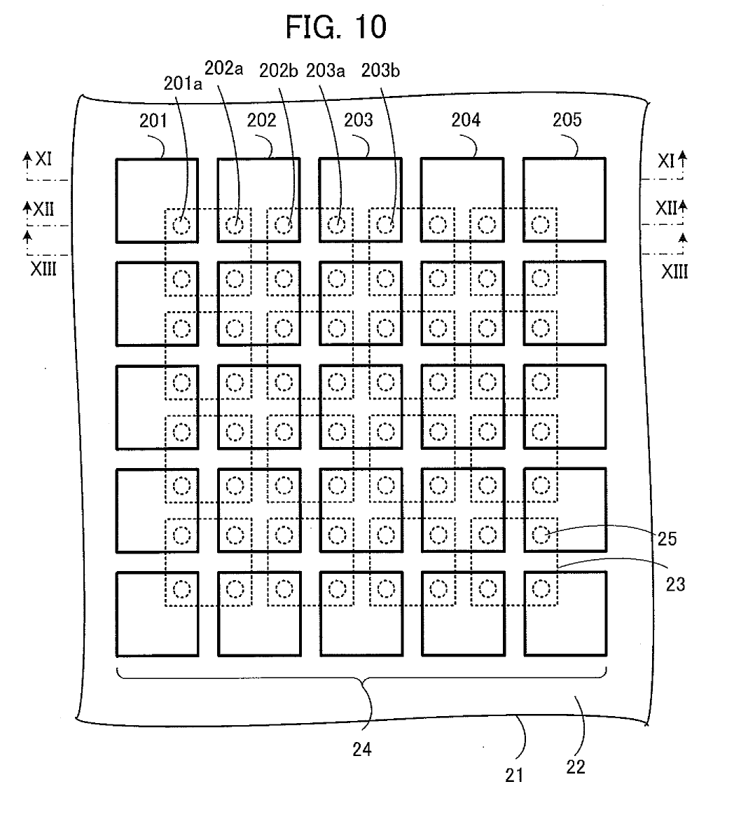

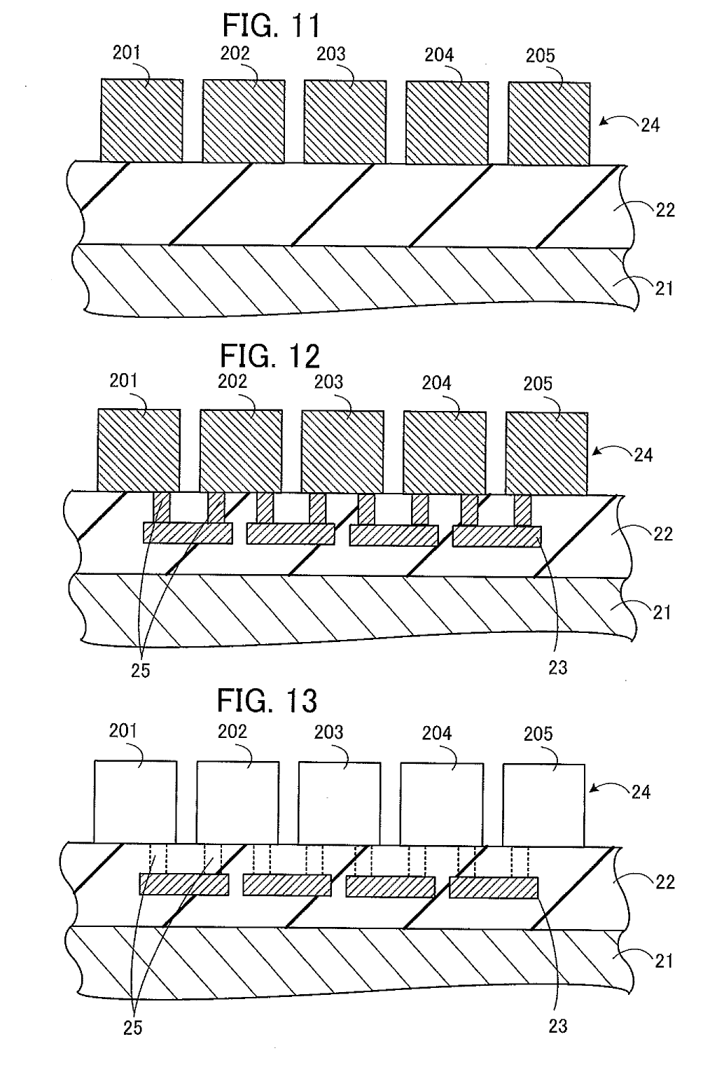

First, an arrangement of a second embodiment will be described. FIG. 10 is a plan view schematically showing a wiring structure of a semiconductor device according to the second embodiment. FIG. 11 is a cross-sectional view schematically showing the wiring structure of FIG. 10 taken along a line XI-XI. FIG. 12 is a cross-sectional view schematically showing the wiring structure of FIG. 10 taken along a line XII-XII. FIG. 13 is a cross-sectional view schematically showing the wiring structure of FIG. 10 taken along a line XIII-XIII.

As shown in FIGS. 10 to 13, a wiring structure of a semiconductor device according to the second embodiment includes an insulating layer (e.g., a SiO₂ layer) 22 formed on a semiconductor substrate (e.g., a silicon substrate) 21 as a base member, a first metal layer 23 as a wiring layer covered with the insulating layer 22, and a second metal layer 24 having a plurality of electrode parts 201, 202, 203, 204, 205, . . . , and so on, which are arranged on the insulating layer 22 to be spaced from each other and which have a thickness larger than that of the first metal layer 23. The insulating layer 22 has a plurality of via holes (e.g., shown by reference numerals 201a, 202a, 202b, 203a, 203b, . . . , and so on) which connect the first metal layer 23 and the plurality of electrode parts 201, 202, 203, 204, 205, . . . , and so on. A plurality of through wiring lines 25 are provided within the plurality of via holes to electrically connect the plurality of electrode parts 201, 202, 203, 204, 205, . . . , and so on to the first metal layer 23.

The plurality of electrode parts 201, 202, 203, 204, 205, . . . , and so on are arranged in a plurality of rows and in a plurality of columns (in five rows and in five columns in the present embodiment). However, the numbers of rows and columns in the array or matrix are not limited to the illustrated example, but may be other numbers of rows and columns such as four rows and four columns, three rows and three columns, or five rows and six columns.

Each of the plurality of electrode parts 201, 202, 203, 204, 205, . . . , and so on has a planar shape of a quadrangle (such as square or a rectangle in the drawing) in a plan view. However, the plurality of electrode parts 201, 202, 203, 204, 205, . . . , and so on are not limited in their planar shape to the illustrated example, but have another shape such as a circle shape, an ellipse shape, or a polygon shape having angular corners different in number from four.

The plurality of via holes 201a, 202a, 202b, 203a, 203b, . . . , and so on are located in the vicinity of angular corners of the electrode parts. However, the plurality of via holes may be provided at other positions.

In the second embodiment, the first metal layer is formed to have a plurality of wiring structural members (in four rows and four columns in the second embodiment), and the plurality of wiring structural members are arranged to be opposed to the plurality of electrode parts with the insulating layer disposed therebetween. In this connection, when the plurality of electrode parts are arranged in M rows and N columns, where each of M and N is an integer not smaller than two, it is desirable that the plurality of wiring structural members be arranged in rows not larger in number than (M−1) and in columns not larger in number than (N−1).

Next, a manufacturing method of the second embodiment will be described. The method of manufacturing the wiring structure of the semiconductor device according to the second embodiment is different from that of the first embodiment in provision of a process of forming the first metal layer 23 into a plurality of wiring structural members using a known etching technique, but is approximately the same as those of the first embodiment in the other points. pp Advantageous effects of the second embodiment will be described. With the wiring structure of the semiconductor device according to the second embodiment, since the second metal layer 24 is formed to have the plurality of electrode parts 201, 202, 203, 204, 205, . . . , and so on, stresses generated within the respective electrode parts are dispersed into the interior of the second metal layer 24 and into a wide range of periphery thereof, so that forces caused by the stresses within the respective electrode parts will not be concentrated on a specific location of the insulating layer 22. For this reason, the insulating layer 22 is less susceptible to forces from the electrode parts, thus avoiding cracking in the insulating layer 22.

In addition, with the wiring structure of the semiconductor device according to the second embodiment, since the first metal layer 23 is formed to have the plurality of wiring parts, stresses generated within the respective wiring parts are dispersed in a wide range, so that forces caused by the stresses of the respective electrode parts will not be concentrated on a specific location of the insulating layer 22. As a result, the insulating layer 22 is less susceptible to forces from the electrode parts of the electrode pad 24, thus avoiding cracking in the insulating layer 22.

As has been explained above, the wiring structure of the semiconductor device and the method of manufacturing the semiconductor device according to the second embodiment, make it possible to reduce generation of a crack in the insulating layer 22 closely contacted with the second metal layer 24, thereby increasing quality and reliability of the wiring structure of the semiconductor device.

The invention being thus described, it will be obvious that the same may be varied in many ways. Such variations are not to be regarded as a departure from the spirit and scope of the invention, and all such modifications as would be obvious to one skilled in the art are intended to be included within the scope of following claims.

What is claimed is:

1. A wiring structure of a semiconductor device, comprising:
an insulating layer formed on a base member;
a first metal layer covered with the insulating layer; and
a second metal layer having a plurality of electrode parts which are arranged on the insulating layer to be spaced from each other and which have a thickness larger than the first metal layer;
wherein the insulating layer has a plurality of via holes which connect the first metal layer and the plurality of electrode parts;
the wiring structure further comprising:
a plurality of through wiring lines which are located within the plurality of via holes and which electrically connect the plurality of electrode parts to the first metal layer.

2. The wiring structure of a semiconductor device according to claim 1, wherein the plurality of electrode parts are arranged in a plurality of rows and in a plurality of columns.

3. The wiring structure of a semiconductor device according to claim 1, wherein:
each of the plurality of electrode parts has a planar shape of a quadrangle, and
the plurality of via holes are located in the vicinity of angular corners of the plurality of electrode parts respectively.

4. The wiring structure of a semiconductor device according to claim 1, wherein:
the first metal layer is made of a single wiring structural member, and
the wiring structural member is located to be opposed to the plurality of electrode parts with the insulating layer disposed therebetween.

5. The wiring structure of a semiconductor device according to claim 1, wherein:
the first metal layer is made of a plurality of wiring structural members, and
the plurality of wiring structural members are located to be opposed to the plurality of electrode parts with the insulating layer disposed therebetween.

6. The wiring structure of a semiconductor device according to claim 5, wherein when the plurality of electrode parts are arranged in M rows and in N columns, each of M and N being an integer not smaller than two, the plurality of wiring structural members are arranged in rows in number not larger than (M−1) and in columns in number not larger than (N−1).

7. The wiring structure of a semiconductor device according to claim 1, wherein the first metal layer, the through wiring lines, and the second metal layer are made of an identical conductive material.

8. The wiring structure of a semiconductor device according to claim 1, wherein the base member is a semiconductor substrate.

9. The wiring structure of a semiconductor device according to claim 1, wherein the base member is another layer formed on a semiconductor substrate.

10. The wiring structure of a semiconductor device according to claim 1, wherein the second metal layer is a pad electrode to which a wiring line is to be bonded.

11. A method of manufacturing a wiring structure of a semiconductor device, comprising:
forming a first insulating layer on a base member;
forming a first metal layer on the first insulating layer;
forming a second insulating layer covering the first metal layer;
forming a plurality of via holes in the second insulating layer;
forming a plurality of through wiring lines which are provided within the plurality of via holes to be electrically connected to the first metal layer; and
forming a plurality of electrode parts which are arranged on the second insulating layer to be spaced from each other and are electrically connected to any of the plurality of through wiring lines, the plurality of electrode parts constituting the second metal layer and having a thickness larger than the first metal layer.

12. The method of manufacturing a wiring structure of a semiconductor device according to claim 11, wherein the plurality of electrode parts are arranged in a plurality of rows and in a plurality of columns.

13. The method of manufacturing a wiring structure of a semiconductor device according to claim 11, wherein each of the plurality of electrode parts has a planar shape of a quadrangle, and the plurality of via holes are arranged in the vicinity of angular corners of the plurality of electrode parts respectively.

14. The method of manufacturing a wiring structure of a semiconductor device according to claim 11, wherein:
the first metal layer is made of a single wiring structural member, and
the wiring structural member is arranged to be opposed to the plurality of electrode parts with the insulating layer disposed therebetween.

15. The method of manufacturing a wiring structure of a semiconductor device according to claim 11, wherein:
the first metal layer is made of a plurality of wiring structural members, and
the plurality of wiring structural members are arranged to be opposed to the plurality of electrode parts with the insulating layer disposed therebetween.

16. The method of manufacturing a wiring structure of a semiconductor device according to claim 15, wherein when the plurality of electrode parts are arranged in M rows and in N columns, each of M and N being an integer not smaller in number than two, the plurality of wiring structural members are arranged in rows not larger in number than (M−1) and in columns not larger in number than (N−1).

17. The method of manufacturing a wiring structure of a semiconductor device according to claim 11, wherein the first metal layer, the through wiring lines, and the second metal layer are made of an identical conductive material.
